(19) United States
(12) Patent Application Publication
(10) Pub. No.: US 2009/0302939 A1
(43) Pub. Date: Dec. 10, 2009

(54) POWER AMPLIFIER WITH DIGITAL PRE-DISTORTION

(76) Inventor: John David Rhodes, Menston (GB)

Correspondence Address: HOWARD & HOWARD ATTORNEYS PLLC, 450 West Fourth Street, Royal Oak, MI, 48067, US

(21) Appl. No.: 12/162,873

(22) PCT Filed: Feb. 1, 2007
(86) PCT No.: PCT/GB07/00337

§ 371 Date: Oct. 24, 2008

(30) Foreign Application Priority Data
Feb. 3, 2006 (GB) 0602147.1

(51) Int. Cl. H03F 1/26

(52) U.S. Cl. 330/149; 330/199

(57) ABSTRACT

A power amplifier using a digitally pre-distorted compound semiconductor transistor is discussed. The amplifier has improved linearity. For a given gate bias voltage, there exists a drain voltage at which the drain current is the same for a pulsed signal as for a DC signal and is invariant to quiescent bias points occurring when a pulsed signal is applied. If an amplifier operates at this point, the trapping effects that lead to memory effects do not affect the dynamic behaviour of a digitally pre-distorted amplifier, resulting in improved linearity. The existence of this point, and it's benefits to the linearity of a digitally pre-distorted amplifier, have not been previously recognised.

The present application relates to amplifiers and in particular to power amplifiers that use a compound semiconductor transistor to amplify a digitally pre-distorted input signal.

Recent telecommunications standards use complex modulation schemes such as Wideband Code Division Multiple Access (WCDMA) and Orthogonal Frequency Division Multiplexing (OFDM) that require highly linear power amplification. Typically, the amplifier is required to operate at microwave frequencies of the order of 10⁹Hz.

Power amplifiers have been proposed that use digital pre-distortion techniques to achieve the necessary linearity. However, in order to function effectively, the relationship between the output of the amplifier and input signal should be independent of the dynamics of the input signal. One way in which the dynamics of the input signal affect the output signal is the action of memory effects. Memory effects are caused by trapping or de-trapping of electrons or holes within the transistor and change the characteristics of the transistor dependent upon the previous values of the input signal.

Pre-distortion algorithms have been proposed that include both memoryless and memory terms to take into account memory effects. The complex coefficients used for any particular amplifier are calculated at full power at a given frequency.

In amplitude modulated signals, such as WCDMA and OFDM, power levels can change rapidly in millisecond time frames. In these circumstances, the performance of the pre-distortion algorithm is reduced because it assumed a full power signal. The linearity of the amplifier can therefore be reduced. One result of the reduced linearity is a rise in the relative power of intermodulation products in the output signal.

It is therefore an object of the present invention to provide a power amplifier in which the linearity of an output signal for an input signal of varying power levels is improved.

The present invention provides a power amplifier having a drain bias voltage and a terminating impedance selected such that, for a given gate bias voltage, the drain current for a DC input signal and the drain current for a pulsed input signal is substantially the same.

According to an aspect of the present invention, there is provided a power amplifier comprising:
a compound semiconductor transistor;
a biasing circuit for setting the drain bias voltage of the compound semiconductor transistor;
a digital pre-distorter for pre-distorting an input signal prior to amplification by the compound semiconductor transistor, wherein the coefficients of the digital pre-distorter are calculated for a modulated signal of maximum power at the fundamental frequency; and
a terminating impedance connected to the compound semiconductor transistor;
wherein the terminating impedance and drain bias voltage are selected such that the resulting load line on a plot of drain current and drain-source voltage is approximately the same as the locus passing through the points on the characteristic curves of the compound semiconductor transistor where the drain current is the substantially the same for a DC signal and a pulsed signal at the same gate bias voltage.

According to another aspect of the present invention, there is provided a method of amplifying a signal using a compound semiconductor transistor, the method comprising:
selecting a drain bias voltage and a terminating impedance for the compound semiconductor transistor such that the resulting load line on a plot of drain current and drain-source voltage is approximately the same as the locus passing through the points on the characteristic curves of the compound semiconductor transistor where the drain current is the substantially the same for a DC signal and a pulsed signal at the same gate bias voltage;
digitally pre-distorting the signal, wherein the coefficients of the digital pre-distorter are calculated for a modulated signal of maximum power at the fundamental frequency; and
supplying the digitally pre-distorted signal to the compound semiconductor transistor.

When the drain-source voltage is referred to as approximately the same as the locus passing through the points on the characteristic curves, this means that the voltage is generally within about 10%, preferably about 5%, more preferably about 1% of the value of the locus at a particular gate bias voltage. Similarly, when the drain current is referred to as substantially the same for a DC signal and a pulsed signal, the drain current need not be exactly the same, but they are generally within about 10%, preferably about 5%, more preferably about 1% of each other.

The present invention is based on the fact that, for a given gate bias voltage, there exists a drain voltage and out put impedance at which the drain current is the same for a pulsed signal as for a DC signal and is invariant to quiescent bias points occurring when a pulsed signal is applied. If an amplifier operates at this point, the trapping effects that lead to memory effects do not affect the dynamic behaviour of a digitally pre-distorted amplifier, resulting in improved linearity. The existence of this point, and it's benefits to the linearity of a digitally pre-distorted amplifier, have not been previously recognised.

The nature of the input signal can be considered to derive a relationship for the terminating impedance. In one embodiment, the compound semiconductor transistor has an invariant locus (i.e. the locus passing through the points on the characteristic curves of the compound semiconductor transistor where the drain current is the substantially the same for a DC signal and a pulsed signal at the same gate bias voltage) which is approximately a straight line. In this embodiment, the compound semiconductor transistor is operated under Class B and the terminating impedance has a value of

$$R = \frac{2 {XV}_{dc}}{{I}_{0}} ,$$

where I₀ is the maximum drain current, V_{dc} drain bias voltage and X is the amplitude of the fundamental frequency of the signal to be amplified.

In another embodiment, the compound semiconductor transistor has a quadratic invariant locus. In this embodiment, the compound semiconductor transistor is operated under Class B and the terminating impedance has a value of

$$R = \frac{{V}_{dc}}{{I}_{0} ( 1 - \frac{2}{3 π} )} ,$$

there I₀ is the maximum drain current and V_{dc} drain bias voltage.

In a further embodiment, the compound semiconductor transistor has an invariant locus at a constant drain voltage. In this embodiment, the compound semiconductor transistor is operated under Class B and the terminating impedance has a value of

$$R = \frac{π}{2} \frac{{V}_{dc}}{{I}_{0}} ,$$

where I₀ is the maximum drain current and V_{dc} is the drain bias voltage.

According to a further aspect of the present invention, there is provided a power amplifier comprising:
a compound semiconductor transistor;
a biasing circuit for setting the drain bias voltage of the compound semiconductor transistor;
a digital pre-distorter for pre-distorting an input signal prior to amplification by the compound semiconductor transistor, wherein the digital pre-distorter is calculated for a continuous signal of maximum power at the fundamental frequency; and
a terminating impedance connected to the compound semiconductor transistor;
wherein the terminating impedance and drain bias voltage are selected such that transient effects are substantially absent from the drain current immediately after a pulsed modulated signal and pulsed Continuous Wave signal have been applied to the transistor.

The transient effects are generally substantially absent when the signal has returned to its quiescent level within a few milliseconds, for example about 20 ms, preferably about 10 ms, more preferably about 5 ms.

According to a still further aspect of the present invention, there is provided a method of amplifying a signal using a compound semiconductor transistor, the method comprising:
selecting a drain bias voltage and a terminating impedance for the compound semiconductor transistor such that such that transient effects are substantially absent from the drain current immediately after a pulsed modulated signal and pulsed Continuous Wave signal have been applied to the transistor;
digitally pre-distorting the signal, wherein the coefficients of the digital pre-distorter are calculated for a continuous signal of maximum power at the fundamental frequency; and
supplying the digitally pre-distorted signal to the compound semiconductor transistor.

By selecting the drain bias voltage and terminating impedance to reduce transient effects, the trapping effects do no not affect a dynamic signal, improving the linearity of the output signal.

In any of the above described aspects and embodiments, the compound semiconductor transistor may be any compound semiconductor device, for example a GaAs, InP or GaN device.

Embodiments of the present invention will now be described by way of example with reference to the accompanying drawings, in which:

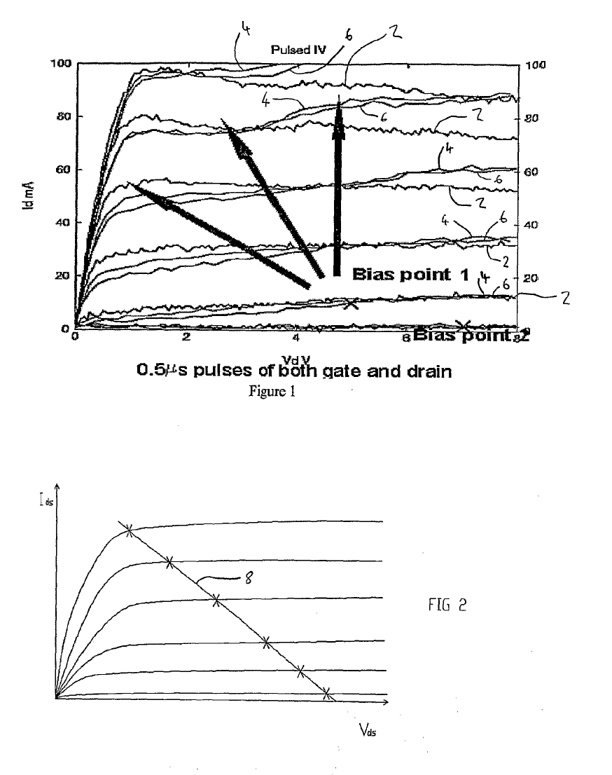

FIG. 1 depicts drain current I_{d} against drain source voltage V_{d} for a GaAs transistor at various gate voltage bias points;

FIG. 2 depicts the invariant locus from FIG. 1 illustrating the principle of the present invention;

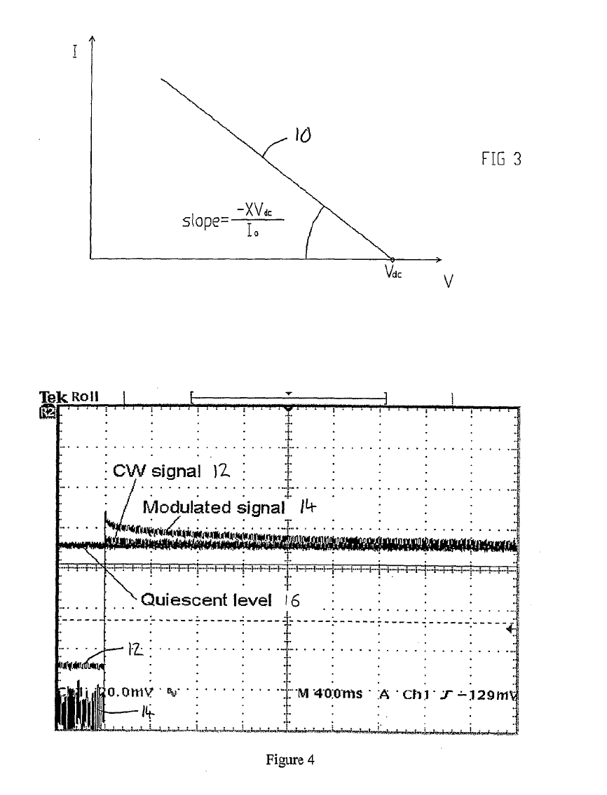

FIG. 3 depicts a load line according to one embodiment of the present invention;

FIG. 4 depicts a typical measured response of a GaN transistor with a modulated and CW signal with a drain bias voltage (V_{dc}) which has not been optimised;

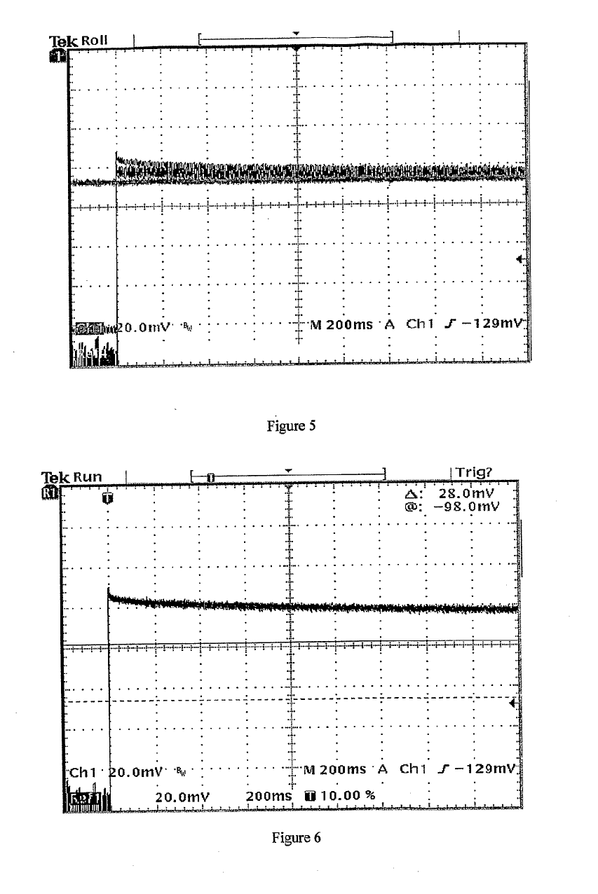

FIGS. 5 and 6 illustrate the effect of gradually increasing the signal power until the transient effects of the CW and modulated signals are the same;

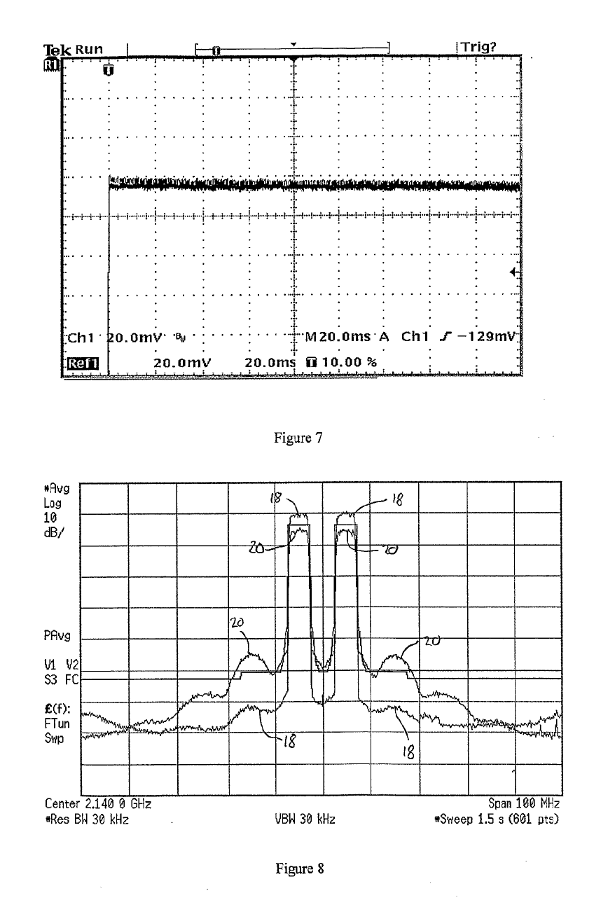

FIG. 7 depicts modulated and CW pulsed signals with the same peak power for which the effects of transients have been removed in an embodiment of the present invention;

FIG. 8 depicts the intermodulation performance of a non-optimised output circuit as known in the prior art;

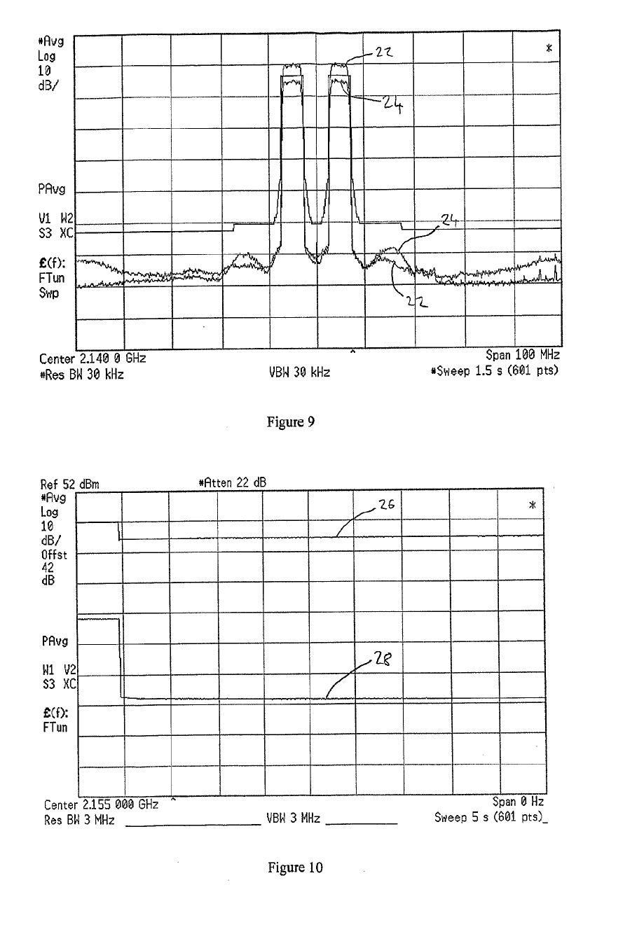

FIG. 9 depicts the intermodulation performance of an output circuit optimised according to the present invention;

FIG. 10 shows the results of intermodulation behaviour with a pulsed signal over time for an output circuit optimised according to the present invention.

FIG. 11 depicts a more general form of the invariant locus for the optimised output of the present invention to approximate;

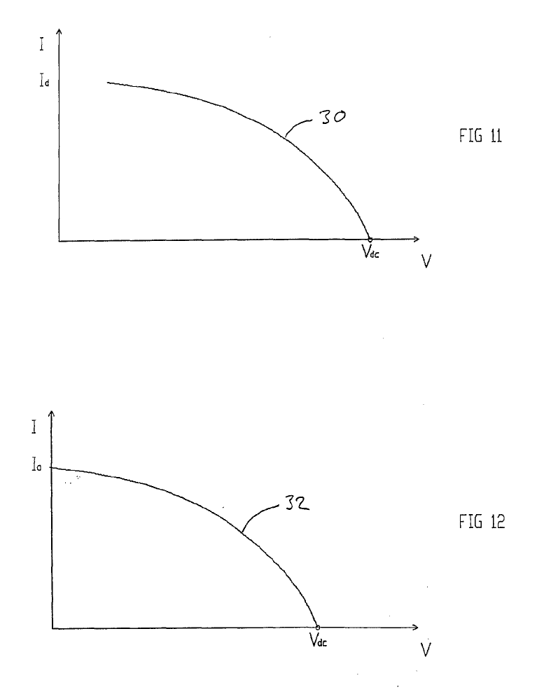

FIG. 12 depicts a load line according to another embodiment of the present invention; and

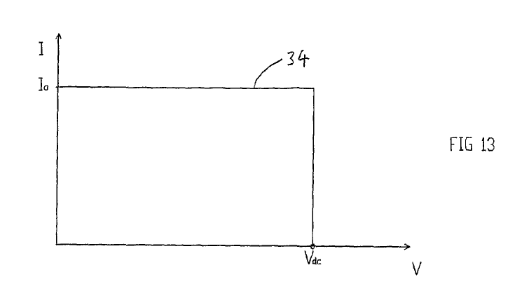

FIG. 13 depicts a load line according to a further embodiment of the present invention.

The present invention is applied to standard power amplifier circuits comprising a semiconductor compound transistor and a digital pre-distorter as are generally known in the art. The digital pre-distorter may be implemented in an Field Programmable Gate Array (FPGA) or a programmable DSP. It may also be implemented using a microprocessor. The digital pre-distorter includes both memory terms and memory-less terms. The coefficients are calculated for a continuous input signal of maximum power at the fundamental frequency in accordance with standard practice known in the art.

The power amplifier circuit includes a terminating network that establishes the load impedance. A biasing circuit establishes the drain bias voltage. Such circuits are generally known to the skilled person. The embodiments of the present invention differ from the prior art in the particular values selected for the terminating network at the fundamental frequency, and in the drain bias voltage. As will be discussed in more detail below, the selection of the terminating impedance and drain bias voltage result in improved linearity.

All embodiments of the present invention operate a compound semiconductor transistor so that the load line resulting from the choice of terminating impedance and drain bias voltage approximates to the locus of points where the drain current is the same for a pulsed signal as for a DC signal and is invariant to quiescent bias points occurring when a pulsed signal is applied.

The existence of these point can be demonstrated by experiments on compound semiconductor transistors. FIG. 1 shows plots of the drain current I_{d} against drain source voltage V_{d} for a GaAs transistor at various gate voltage bias points. The curves 2 are under DC conditions. The traces 4 and 6 are plots at the same set of gate bias voltages with different quiescent drain bias conditions and low duty cycle pulses applied of 0.5 μs duration. The reduction of drain current at low drain voltages is primarily due to electron trapping. The increase in drain current at higher drain voltages is primarily due to hole-trapping.

FIG. 1 shows that for each gate bias voltage, there exists a drain voltage at which the drain current is the same as the DC current and is invariant to the quiescent bias points when a pulsed signal is applied. FIG. 2 depicts an approximate locus 8 of these drain voltages, which forms a load line according to the present invention. It can be seen that in this case the locus approximates to a straight line.

The present invention provides an RF impedance termination so that the transistor operates on a load line that follows the locus 8 of the points in FIG. 2. The required impedance termination can be approximated by analysing the transistor with knowledge of the constraints on the transistor's operation.

For maximum efficiency, the amplifier is operated in Class B. In that case the drain current I_{d} has the form:

$$\begin{matrix}{I}_{d} = {I}_{0} sin θ & θ = 0 \to π \\ = 0 & θ = π \to 2 π\end{matrix} \qquad ( 1 )$$

where I₀ is the amplitude of the drain current. The Fourier Series representation is:

$$I = {I}_{0} ( \frac{1}{π} + \frac{1}{2} sin θ - \frac{2}{π} ( \frac{cos 2 θ}{3} + \frac{cos 4 θ}{15} + \frac{cos 6 θ}{35} … ) ) \qquad ( 2 )$$

If the output voltage is constrained to be devoid of harmonics then:

V=V_{dc}(1−X sin θ) (3)

where X is the amplitude of the fundamental frequency and X≦1. From this analysis, the locus in the I-V plane (the load line in FIG. 2) is:

$$\begin{matrix}\begin{matrix}V = {V}_{dc} ( 1 - \frac{XI}{{I}_{0}} ) & θ = 0 \to π\end{matrix} \\ and & ( 4 ) \\ \begin{matrix}I = 0 , V \geq {V}_{dc} & θ = π \to 2 π\end{matrix} & ( 5 )\end{matrix}$$

Equation (4) is a straight line with a slope of

$$- \frac{{XV}_{dc}}{{I}_{0}} \qquad ( 6 )$$

and V=V_{dc} when I=0. The resulting locus 10 is illustrated in FIG. 3.

If the terminating load is a resistor at the fundamental frequency, having a value of R, then from equations (2) and (3)

$$R = \frac{2 {XV}_{dc}}{{I}_{0}} \qquad ( 7 )$$

and hence the slope of the load line is

$$- \frac{R}{2} .$$

Therefore the value of V_{dc} and R can be chosen such that the resulting load line follows the locus 8 shown in FIG. 2.

Alternatively, V_{dc} and R can also be determined by applying pulsed modulated or Continuous Wave (CW) to a compound semiconductor transistor. The drain current is measured as a function of time immediately after the pulse has been removed. This can be done by measuring the voltage across a resistor in the drain/source circuit. FIG. 4 depicts a typical measured response of a GaN transistor with a modulated signal 12 and a CW signal 14 with a drain bias voltage (V_{dc}) which has not been optimised. The average powers of the two signals are same. FIG. 4 also depicts the quiescent level 16. It can be seen that the undershoot on the modulated signal is significantly greater than that of the CW signal indicating that the effect is trap related and not thermally related. FIGS. 5 and 6 illustrate the effect of gradually increasing the signal power until the transient effects of the CW and modulated signals are the same (FIG. 6). This occurs at the same peak signal level and therefore is highly likely to be caused by trapping effects.

If the drain voltage is then adjusted together with the effective load impedance at the fundamental frequency, the transient effect can be substantially removed. FIG. 7 depicts this result for both the modulated and CW pulsed signals with the same peak power.

As proof that the present invention arrives at the optimum load and drain voltage bias condition a full power WCDMA signal was used to determine coefficients for a digital pre-distorter for supplying a signal to compound semiconductor transistor. FIG. 8 depicts the intermodulation performance of a non-optimised output circuit. The full power signal is depicted by trace 18 and an input signal reduced in power by 6 dB is shown by trace 20. When the input signal is reduced in power by 6 dB, the intermodulation products increase by 15 dB. FIG. 9 depicts the intermodulation performance of an optimised output circuit. The full power signal is depicted by trace 22 and an input signal reduced in power by 6 dB is shown by trace 24. When the input signal is reduced in power by 6 dB, the intermodulation products only increase in power by 3 dB.

FIG. 10 shows the results of measurement of the behaviour with a pulsed signal. The power in the 3^{rd} ordered intermodulation product was measured as a function of time in a 3 MHz bandwidth. A non-optimised circuit is depicted by trace 26, and an optimised circuit by trace 28. The optimised solution is clearly significantly better as a function of time.

In the cases discussed above, the locus approximated to a straight line, in general this will not be case for most transistors. A more general solution of the locus 30 is shown in FIG. 11. The load line corresponding to this locus is approximated by increasing the input signal so that the output current starts to saturate. One such output current is:

$$\begin{matrix}I = 2 {I}_{0} sin θ ( 1 - \frac{1}{2} sin θ ) & θ = 0 \to π \\ = 0 & θ = π \to 2 π\end{matrix} \qquad ( 8 )$$

The Fourier Series is:

$$\frac{I}{{I}_{0}} = \frac{2}{π} - \frac{1}{4} + ( 1 - \frac{2}{3 π} ) sin θ - ( \frac{4}{3 π} - \frac{1}{4} ) sin 2 θ + \frac{4}{15} sin 3 θ … \qquad ( 9 )$$

If again the output voltage is constrained to be devoid of harmonics then:

V=V_{dc}(1−X sin θ) (10)

where X≦1. Thus, for X=1, the locus in the IV plane is:

$$\frac{I}{{I}_{0}} = 1 - {( \frac{V}{{V}_{dc}} )}^{2} \qquad ( 11 )$$

This locus 32 is illustrated in FIG. 12. It is a close approximation to FIG. 11 if the load resistance R is given by:

$$R = \frac{{V}_{dc}}{{I}_{0} ( 1 - \frac{2}{3 π} )} \qquad ( 12 )$$

If the input signal is increased further, the current tends towards a square wave defined by:

$$\begin{matrix}I = {I}_{0} & θ = 0 \to π \\ = 0 & θ = π \to 2 π\end{matrix} \qquad ( 13 )$$

This has a Fourier Series:

$$\frac{I}{{I}_{0}} = \frac{1}{2} + \frac{2}{π} ( sin θ + \frac{1}{3} sin 3 θ + \frac{1}{5} sin 5 θ … ) \qquad ( 14 )$$

The locus in the limiting case is the locus 34 depicted in FIG. 13 with

$$R = \frac{π}{2} \frac{{V}_{dc}}{{I}_{0}} \qquad ( 15 )$$

Although the embodiments have been described with reference to a single compound semiconductor transistor, in alternate embodiments more than one transistor can be used.

1. A power amplifier comprising:
a compound semiconductor transistor;
a biasing circuit for setting the drain bias voltage of the compound semiconductor transistor;
a digital pre-distorter for pre-distorting an input signal prior to amplification by the compound semiconductor transistor, wherein the coefficients of the digital pre-distorter are calculated for a modulated signal of maximum power at the fundamental frequency; and
a terminating impedance connected to the compound semiconductor transistor;
wherein the terminating impedance and drain bias voltage are selected such that the resulting load line on a plot of drain current and drain-source voltage is approximately the same as the locus passing through the points on the characteristic curves of the compound semiconductor transistor where the drain current is substantially the same for a DC signal and a pulsed signal at the same gate bias voltage.

2. A method of amplifying a signal using a compound semiconductor transistor, the method comprising:
selecting a drain bias voltage and a terminating impedance for the compound semiconductor transistor such that the resulting load line on a plot of drain current and drain-source voltage is approximately the same as the locus passing through the points on the characteristic curves of the compound semiconductor transistor where the drain current is the substantially the same for a DC signal and a pulsed signal at the same gate bias voltage;
digitally pre-distorting the signal, wherein the coefficients of the digital pre-distorter are calculated for a modulated signal a/maximum power at the fundamental frequency; and
supplying the digitally pre-distorted signal to the compound semiconductor transistor.

3. A power amplifier according to claim 1, wherein the compound semiconductor transistor is operated under Class B and the terminating impedance has a value of
$$R = \frac{2 {XV}_{dc}}{{I}_{0}}$$
where I₀ is the maximum drain current, V_{dc} is the drain bias voltage and X is the amplitude of the fundamental frequency of the signal to be amplified.

4. A power amplifier according to claim 1, wherein the compound semiconductor transistor is operated under Class B and the terminating impedance has a value of
$$R = \frac{{V}_{dc}}{{I}_{0} ( 1 - \frac{2}{3 π} )} ,$$
where I₀ is the maximum drain current and V_{dc} is the drain bias voltage.

5. A power amplifier according to claim 1, wherein the compound semiconductor transistor is operated under Class B and the terminating impedance has a value of
$$R = \frac{π}{2} \frac{{V}_{dc}}{{I}_{0}}$$
where I₀ is the maximum drain current and V_{dc} is the drain bias voltage.

6. A power amplifier comprising:
a compound semiconductor transistor;
a biasing circuit for setting the drain bias voltage of the compound semiconductor transistor;
a digital pre-distorter for pre-distorting an input signal prior to amplification by the compound semiconductor transistor, wherein the digital pre-distorter is calculated for a continuous signal of maximum power at the fundamental frequency; and
a terminating impedance connected to the compound semiconductor transistor;
wherein the terminating impedance and drain bias voltage are selected such that transient effects are substantially absent from the drain current immediately after a pulsed modulated signal and a pulsed Continuous Wave signal have been applied to the transistor.

7. A method of amplifying a signal using a compound semiconductor transistor, the method comprising:
selecting a drain bias voltage and a terminating impedance for the compound semiconductor transistor such that such that transient effects are substantially absent from the drain current immediately after a pulsed modulated signal and a pulsed Continuous Wave signal have been applied to the transistor;
digitally pre-distorting the signal, wherein the coefficients of the digital predistorter are calculated for a continuous signal of maximum power at the fundamental frequency; and
supplying the digitally pre-distorted signal to the compound semiconductor transistor.

8. A power amplifier according to claim 1, wherein the compound semiconductor transistor is a GaAs, InP or GaN device.

9. A method according to claim 2, wherein the compound semiconductor transistor is operated under Class B and the terminating impedance has a value of
$$R = \frac{2 {XV}_{dc}}{{I}_{0}} ,$$
where I₀ is the maximum drain current, V_{dc} is the drain bias voltage and X is the amplitude of the fundamental frequency of the signal to be amplified.

10. A method according to claim 2, wherein the compound semiconductor transistor is operated under Class B and the terminating impedance has a value of
$$R = \frac{{V}_{dc}}{{I}_{0} ( 1 - \frac{2}{3 π} )} ,$$
where I₀ is the maximum drain current and V_{dc} is the drain bias voltage.

11. A method according to claim 2, wherein the compound semiconductor transistor is operated under Class B and the terminating impedance has a value of
$$R = \frac{π}{2} \frac{{V}_{dc}}{{I}_{0}} ,$$
where I₀ is the maximum drain current and V_{dc} is the drain bias voltage.
